(19) United States
(12) Patent Application Publication
(10) Pub. No.: US 2026/0366157 A1
(43) Pub. Date: Nov. 19, 2026

(54) MULTl-CHANNEL PRECURSOR DELIVERY SYSTEM

(71) Applicant: Lam Research Corporation, Fremont, CA (US)

(72) Inventors: Harish Kumar Premakumar, Bengaluru (IN); Kyle Watt Hart, Beaverton, OR (US); Adam Fisher, Portland, OR (US); Awnish Gupta, Hillsboro, OR (US); Shoa Allene Russell, West Linn, OR (US); Chandrashekar Rakesh, Bangalore (IN); Steven Payonk Letourneau, Portland, OR (US)

(21) Appl. No.: 19/477,313

(22) PCT Filed: Apr. 23, 2024
(86) PCT No.: PCT/US2024/025877

§ 371 Date: Oct. 21, 2025

Related U.S. Application Data
(60) Provisional application No. 63/499,532, filed on May 2, 2023.

(51) Int. Cl. C23C 16/455; C23C 16/458; C23C 16/52

(52) U.S. Cl. CPC C23C 16/45561; C23C 16/4583; C23C 16/52

(57) ABSTRACT

A precursor delivery system for supplying a precursor to a process chamber includes a housing, and a detachable precursor dispensing assembly detachably coupled to the housing and configured to supply the precursor to the process chamber, wherein the detachable precursor dispensing assembly includes an ampoule, and a first valve assembly fluidly coupled to the ampoule, and including, a first valve, a second valve, a third valve, and a fourth valve. The precursor delivery system also includes a controller. WO

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

In some semiconductor processing operation, e.g., deposition operations, a chemical precursor may be stored in an ampoule and delivered to a process chamber to form a layer on a substrate. A chemical precursor may be mixed with a carrier gas in the ampoule. For some deposition operations, more than one chemical precursors are delivered to the process chamber.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Provided is a precursor delivery system for supplying one or more precursors to a process chamber. The precursor delivery system includes a housing including a front cover, a rear cover, a top cover, a bottom cover, and two side covers, a detachable precursor dispensing assembly detachably coupled to the housing and configured to supply the precursor to the process chamber. The detachable precursor dispensing assembly includes: an ampoule configured to receive and supply the precursor to the process chamber; and a first valve assembly fluidly coupled to the ampoule. The first valve assembly includes: a first valve fluidly coupled with a first inlet to the ampoule and a precursor source supply, a second valve fluidly coupled with a second inlet to the ampoule and a source gas supply, a third valve fluidly coupled with an outlet of the ampoule and an inner vapor out line, and a fourth valve fluidly coupled with a first junction between the second valve and the fourth valve, and a second junction between the third valve and the fourth valve; and a controller for controlling operation of the precursor delivery system.

In some embodiments, the detachable precursor dispensing assembly also includes a second valve assembly, the second valve assembly includes a fifth valve fluidly coupled with the second valve and a flow controller, a sixth valve and a seventh valve fluidly coupled with the first valve and a vacuum source, and an eighth valve fluidly coupled with the precursor source supply with the first valve.

In some embodiments, the inner vapor out line bypasses the second valve assembly.

In some embodiments, the second valve assembly is positioned above the first valve assembly.

The precursor delivery system also includes a vapor out line detachably coupled to the rear cover of the housing and fluidly coupled to the ampoule of the detachable precursor dispensing assemblies, and a conduit fluidly coupled to the vapor out line, wherein the conduit comprises a distribution point that is fluidly coupled to a showerhead of the process chamber, and wherein the conduit is positioned proximate to the bottom of or below the precursor delivery system.

The precursor delivery system also includes a manometer positioned outside the housing, wherein the manometer is fluidly coupled to the conduit.

The precursor delivery system also includes an elbow valve that fluidly couples the inner vapor out line with the vapor out line.

In some embodiments, the precursor includes a silicon-containing precursor.

Another aspect of the disclosure relates to an apparatus for processing one or more substrates. The apparatus includes one or more process chambers. Each process chamber includes a chuck for supporting a substrate, and a precursor delivery system for supplying one or more precursors into the process chamber for forming a film. The precursor delivery system includes a housing comprising a front cover, a rear cover, a top cover, a bottom cover, and two side covers; and one or more detachable precursor dispensing assemblies detachably received in the housing. Each of the one or more detachable precursor dispensing assemblies includes an ampoule configured to store the precursor, and a first valve assembly fluidly coupled to the ampoule. The first valve assembly includes a first valve fluidly coupled with a first inlet to the ampoule and a precursor source supply, a second valve fluidly coupled with a second inlet to the ampoule and a source gas supply, a third valve fluidly coupled with an outlet of the ampoule and an inner vapor out line, and a fourth valve fluidly coupled with a first junction between the second valve and the fourth valve, and a second junction between the third valve and the fourth valve. The precursor delivery system also includes a controller for controlling operation of the precursor delivery system. The apparatus also includes a controller including program instructions for causing the ampoule to receive the precursor from the precursor source supply, causing the carrier gas to flow from the source gas supply to the ampoule to form a mixture including the precursor and the carrier gas, and causing the mixture to flow from the ampoule into the process chamber.

In some embodiments, the each of the one or more detachable precursor dispensing assemblies further includes a second valve assembly. The second valve assembly includes a fifth valve fluidly coupled with the second valve and a flow controller, a sixth valve and a seventh valve fluidly coupled with the first valve and a vacuum source; and an eighth valve fluidly coupled with the precursor source supply with the first valve.

In some embodiments, the inner vapor out line bypasses the second valve assembly.

In some embodiments, the second valve assembly is positioned above the first valve assembly.

In some embodiments, the precursor delivery system further comprises one or more vapor out lines fluidly coupled to the ampoules of the one or more detachable precursor dispensing assemblies; and a conduit fluidly coupled to the one or more vapor out lines, wherein the conduit comprises a distribution point that is fluidly coupled to one or more showerheads in the one or more process chambers, respectively, wherein the conduit is positioned proximate to the bottom of or below the precursor delivery system.

In some embodiments, the precursor delivery system further includes a manometer positioned outside the housing, wherein the manometer is fluidly coupled to the conduit.

In some embodiments, the each of the one or more detachable precursor dispensing assemblies further includes an elbow valve that fluidly couples the inner vapor out line with the one or more vapor out lines in the each of the one or more detachable precursor dispensing assemblies.

In some embodiments, the apparatus is configured for atomic layer deposition, plasma enhanced atomic layer deposition, chemical vapor deposition, or plasma enhanced chemical vapor deposition.

The apparatus also includes a remote plasma source.

In some embodiments, the one or more precursors include a silicon-containing precursor.

These and other features of the disclosed embodiments will be described in detail below with reference to the associated drawings.

### BRIEF DESCRIPTION OF DRAWINGS

FIG. 1 shows a perspective view of an example precursor delivery system for a process chamber according to some embodiments.

FIG. 2 shows an interior of an example precursor delivery system according to some embodiments.

FIG. 3 shows a schematic flow diagram for a precursor and a carrier gas in an example precursor delivery system according to some embodiments.

FIG. 4 shows a magnified view of an interior of an example precursor delivery system for delivery of a precursor and carrier gas according to some embodiments.

FIG. 5 shows an exterior of the example precursor delivery system of FIG. 4 for delivery of a precursor and carrier gas according to some embodiments.

FIG. 6 shows an example rear view of an example precursor delivery system according to some embodiments.

FIG. 7 depicts a schematic diagram of an example processing apparatus for delivering precursors according to some embodiments.

### DETAILED DESCRIPTION

In the following description, numerous specific details are set forth to provide a thorough understanding of the presented embodiments. The disclosed embodiments may be practiced without some or all these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

In the present disclosure, the terms “semiconductor wafer,” “wafer,” “substrate,” and “film on a substrate” are used interchangeably. One of ordinary skill in the art would understand that the term “film on a substrate” can refer to one or more partially fabricated integrated circuits formed on a substrate during any of many stages of integrated circuit fabrication. A wafer or substrate used in the semiconductor device industry typically has a diameter of 200 mm, or 300 mm, or 450 mm. The following detailed description assumes the present disclosure is implemented on a wafer. However, the present disclosure is not so limited. The work piece may be of various shapes, sizes, and materials. In addition to semiconductor wafers, other work pieces that may take advantage of the present disclosure include various articles such as printed circuit boards and the like.

In the present disclosure, the terms “depositing,” and “forming” are used interchangeably. Also, the terms “layer,” “film,” and “thin film” are used interchangeably. One of ordinary skill in the art would understand that “forming” a “layer” in any of many stages of integrated circuit fabrication can refer to “depositing” a “film” or “thin film” by one of various film forming methods such as including chemical vapor deposition (CVD), plasma enhanced chemical vapor deposition (PECVD), atomic layer deposition (ALD), or plasma enhanced atomic layer deposition (PEALD) due to the decreased feature sizes in a semiconductor device.

Semiconductor device manufacturing typically involves various deposition processes to deposit films to form integrated circuits and related devices on the substrate by various methods including CVD, PECVD, ALD, or PEALD, where a gas mixture including one or more precursors may be introduced into the process chamber to deposit a film on the substrate. In some substrate processing systems, a radio frequency (RF) plasma may be used to activate chemical reactions. ALD or PEALD are film deposition processes which are well-suited to the deposition of conformal films due to the fact that a single cycle of ALD or PEALD deposits a single thin layer of material, the thickness being limited by the amount of one or more precursors which may adsorb onto the substrate surface (i.e., forming an adsorption-limited layer) prior to the film-forming chemical reaction itself. Multiple “ALD cycles” may then be used to build up a film of the desired thickness, and since each layer is thin and conformal, the resulting film substantially conforms to the shape of the underlaying device structure. In certain embodiments, each ALD or PEALD cycle includes the operations: (1) exposure of the substrate surface to a first precursor, (2) purge of the process chamber in which the substrate is located, (3) activation of a reaction of the substrate surface, typically with a plasma and/or a second precursor, and (4) purge of the process chamber in which the substrate is located. The first step listed herein may be referred to as a “dose step,” the second step may be referred to as a “purge step,” the third step may be referred to as a “RF step,” and the fourth step may be referred to as a “RF purge step.” ALD or PEALD processes may typically involve one or more precursors to deposit a film on the substrate according to the above-described steps of operations.

For providing one or more precursors, CVD, PECVD, ALD, or PEALD processes may be provided with a precursor delivery system. The precursor delivery system may typically include one or two channels. The channel may refer to an ampoule in which a precursor is stored. For example, two channels may refer to two ampoules storing precursors that may be supplied to a process chamber for forming films on the substrates. In another example, the channel may refer to a detachable assembly including an ampoule. The precursor may be supplied from a precursor supply source, stored in the ampoule, and, depending on the process instructions, the precursor may be introduced into the process chamber for forming a film on a substrate. A carrier gas (e.g., a push gas such as nitrogen, helium, or argon) may be mixed with the precursor in the interior of the ampoule to transport the precursor along the gas lines to the process chamber. A precursor may be a liquid precursor or a gas precursor. Some of the gas precursors may be generated by vaporizing a liquid precursor.

The present disclosure relates to a precursor delivery system accommodating three or more channels in an ordinary dimension used for housing two or fewer channels. Accommodating three or more channels in a compact housing design that is now in use was not achieved before. Typically for a precursor delivery system used in conjunction with a thin film deposition apparatus, two or fewer channels (e.g., ampoules) may be populated in the precursor delivery system to provide one or two precursors to a process chamber for depositing a film. In some semiconductor fabrication operations, supplying three or more channels may be necessary. The inventors of the present disclosure surprisingly found that three or more channels can be populated in a compact precursor delivery system where only two or fewer channels were previously populated and no previous success for housing three or more channels was observed. The problem of accommodating three or more channels in a compact precursor delivery system would not have been solved without the embodiments described in this disclosure.

The precursor delivery system according to some embodiments may include an ampoule, multiple valves and/or fittings, and gas lines fluidly connecting the ampoule, valves and/or fittings, and the process chamber. In a precursor delivery system, instead of populating two or less channels, three or more channels may be populated in the interior of the precursor delivery system without modifying the overall dimension of the precursor delivery system. Additionally, new design of the precursor delivery system allows the length of the gas lines, such as the gas line length between the ampoule and the process chamber to be reduced. The reduced gas line length may be beneficial in shortening a purging time prior to and/or after a deposition process. For example, less time may be required in supplying a carrier gas from a gas source supply to the process chamber when the gas line length is reduced, thereby reducing the overall time for a deposition process and increasing the throughput. The reduced gas line length may also improve process gas timing to minimize delays in delivery of process gases to the process chamber. Additionally, the precursor delivery system according to some embodiments allow the number of valves and fittings to be reduced, which may be beneficial in reducing the overall manufacturing and maintenance cost. Further, the precursor delivery system allows improved serviceability. For example, an easy access to the interior of the precursor delivery system is achieved, which is beneficial for maintenance or repair.

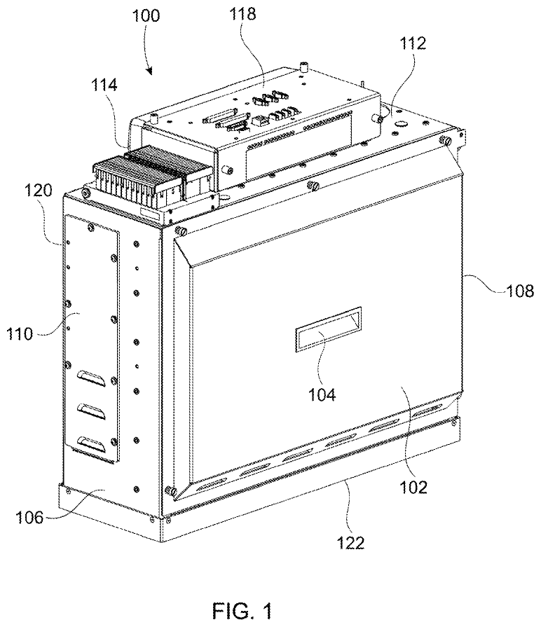

FIG. 1 shows a perspective view of an example precursor delivery system for a process chamber according to some embodiments. The precursor delivery system 100 may detachably accommodate up to three detachable precursor dispensing assemblies therein. In some embodiments, one, two, or three detachable precursor dispensing assemblies may be populated in the interior of the precursor delivery system 100. However, it will be understood that four or even more detachable precursor dispensing assemblies may be populated in the interior of the precursor delivery system 100. Each detachable precursor dispensing assembly may include an ampoule. In some embodiments, the precursor delivery system 100 may be a housing including a front cover 102 that may be removably attached to the precursor delivery system 100 by a hinge system or other suitable coupling means. The front cover 102 may include an opening 104 through which an interior may be seen. The housing may also include two side covers 106 and 108, each including a removable cover 110; and a top cover 112 including one or more connectors 114 for sending and receiving signals from a controller, and a controller 118 for controlling the operation of the precursor delivery system. The controller 118 may include a microprocessor, and a memory that may store a process recipe and control the flow of the precursor in and out of each ampoule, independently or in combination with a controller of an apparatus to which the precursor delivery system is operably and fluidly coupled. The removable covers 110 on both side covers 106 and 108 may provide improved access to the interior of the precursor delivery system 100. The housing may also include a rear cover 120, and a bottom cover 122. In some embodiments, the dimension of the housing may be about 66 cm (width)×about 54 cm (height)×about 25 cm (depth), or about 62 cm (width)×about 50 cm (height)×about 21.5 cm (depth).

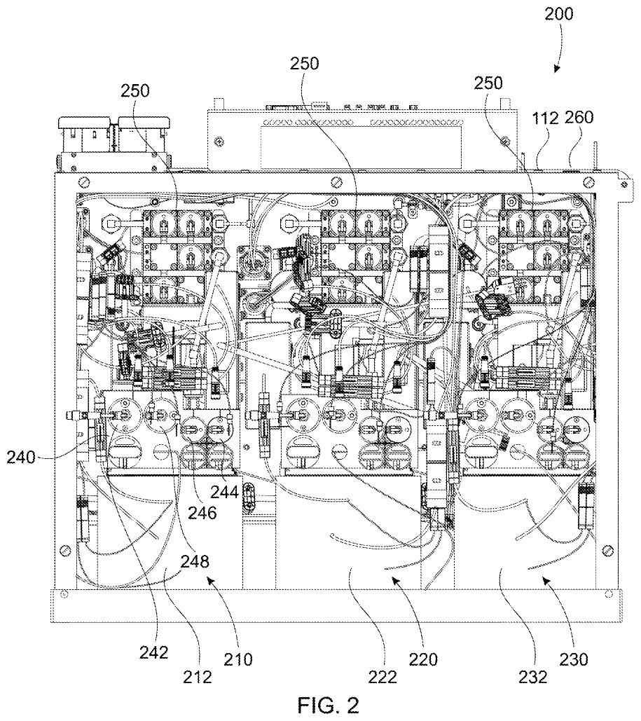

FIG. 2 shows an interior of an example precursor delivery system 200 according to some embodiments. The precursor delivery system 200 may be configured to detachably accommodate at least three detachable precursor dispensing assemblies 210, 220, and 230 in the precursor delivery system 200. In some embodiments, depending on the process instructions, only one or two detachable precursor dispensing assemblies may be received in the precursor delivery system 200, leaving space for at least two or one unused detachable precursor dispensing assemblies empty. In some embodiments, the at least three detachable precursor dispensing assemblies 210, 220, and 230 may be accommodated in the precursor delivery system 200 to provide one or more precursors into one or more process chambers. In some embodiments, the dimensions of the detachable precursor dispensing assemblies 210, 220, and 230 may be substantially identical, and the overall dimensions of each detachable precursor dispensing assembly may be about 24 cm (width)×about 47 cm (height)×about 27 cm (depth), or about 19 cm (width)×about 42 cm (height)×about 22.5 cm (depth).

Each detachable precursor dispensing assembly 210, 220, and 230 may include an ampoule 212, 222, and 232, respectively. One chemical precursor may be stored in each ampoule for supplying a controlled dose into a process chamber. In some embodiments, each ampoule may have a volume of between about 500 mL and about 3 L. In some cases, each of the three ampoules 212, 222, and 232 may store different precursors from other ampoules. In some cases, at least two of the three ampoules 212, 222, and 232 may store a single precursor while the other of the three ampoules 212, 222, and 232 may store a different precursor. In some cases, all three ampoules 212, 222, and 232 may store a single precursor. In some embodiments, each ampoule may be provided with a heating element to maintain the temperature of the precursor at a certain temperature before carrying the precursor out of the ampoule.

Each detachable precursor dispensing assembly 210, 220, and 230 may also include a first valve assembly 240 fluidly coupled to each ampoule 212, 222, and 232. For the sake of simplicity, the first valve assembly 240 may be described only with respect to the detachable precursor dispensing assembly 210.

The first valve assembly 240 may include a third valve 242 (i.e. vapor out valve) configured to open or close the flow of the precursor from the ampoule 212. The third valve 242 (i.e., vapor out valve) may be positioned proximate to the ampoule 212, fluidly connected to an outlet (i.e., outlet port) of the ampoule 212 to an inner vapor out line (not shown) positioned in the interior of the precursor delivery system 200. The first valve assembly 240 also includes a second valve 244 (i.e. carrier gas in valve) fluidly connected to a second inlet of the ampoule 212, where the second valve 244 fluidly connects the second inlet of the ampoule 212 with an outlet of a source gas supply (not shown). The first valve assembly 240 may also include a first valve 246 (i.e. precursor fill valve) fluidly connected to a first inlet (not shown) of the ampoule 212, where the first valve 246 fluidly connects the first inlet of the ampoule 212 with an outlet of the precursor source supply (not shown). The first valve assembly 240 may also include a bypass valve 248 configured to divert the carrier gas without passing through the ampoule 212. The first valve assembly 240 in each detachable precursor dispensing assembly may operate independently from the first valve assemblies in other detachable precursor dispensing assemblies in the precursor delivery system 200.

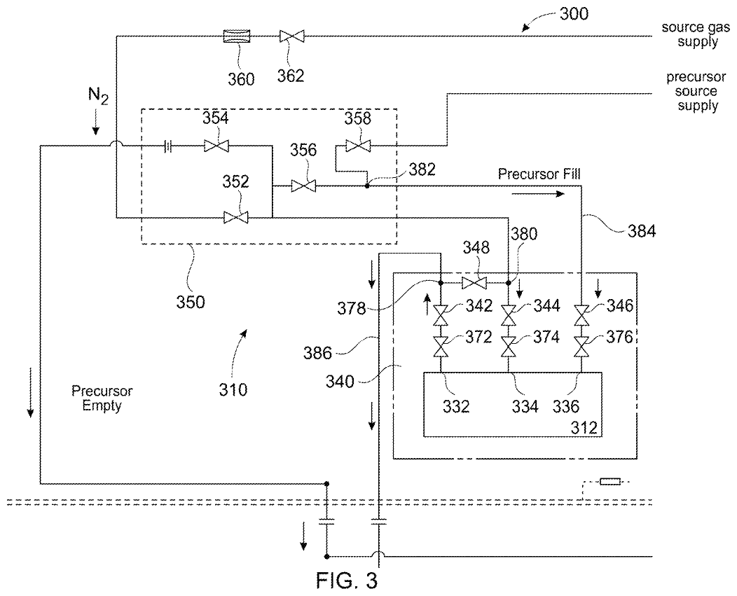

Each detachable precursor dispensing assembly 210, 220, and 230 may also include a second valve assembly 250 configured to receive the precursor and the carrier gas from the source gas supply and the precursor source supply, and provide through multiple gas lines to the various valves in the first valve assembly 240. In some embodiments, the second valve assembly 250 may be positioned on the upper portion of the precursor delivery system 200. In some embodiments, the second valve assembly 250 may be positioned above the first valve assembly 240. These valves may be populated within a certain space in the precursor delivery system to preserve real estate and further reduce the overall dimension and footprint of the precursor delivery system. In one example, the second valve assembly 250 may include four valves, which may be further described in detail with respect to FIG. 3. The precursor delivery system 200 may also be provided with an exhaust 260 formed on one side of the top cover 112 such that a precursor or a carrier gas, in case a leak occurs from any of the ampoules 212, 222, or 232, gas lines, or valves, may be vented, exhausted, or otherwise removed from the interior of the precursor delivery system 200. The second valve assembly 250 in the detachable precursor dispensing assembly 210 may be configured to operate independently from the second valve assemblies in other detachable precursor dispensing assemblies.

FIG. 3 shows a schematic flow diagram for a precursor and a carrier gas in an example precursor delivery system according to some embodiments. For example, the flow diagram in FIG. 3 may describe the flow of a precursor and a carrier gas in and out of one of the detachable precursor dispensing assemblies 210, 220, and 230 in the precursor delivery system 200 in FIG. 2. However, the flow diagram in FIG. 3 is not limited to only one detachable precursor dispensing assembly in the precursor delivery system. Instead, the flow diagram in FIG. 3 may also be applied to any number of detachable precursor dispensing assemblies operating independently or in combination with other detachable precursor dispensing assemblies in a precursor delivery system 300. The precursor delivery system 300 may include a detachable precursor dispensing assembly 310 including an ampoule 312, a first valve assembly 340, a second valve assembly 350, and a flow controller 360. In FIG. 3, a gas line and/or pipe of the example precursor delivery system 300 is depicted as a line, and a valve is depicted as a “bowtie” (e.g., two opposing triangles). The flow direction of the precursor and/or the carrier gas is depicted as an “arrow.” For the purposes of this disclosure, the phrase “gas line section” and/or “gas line” may be used to describe any gas line in the precursor delivery system that fluidly connect one or more ampoules, one or more first valve assemblies, one or more second valve assemblies, one or more process chambers, one or more source gas supplies, and one or more precursor source supplies.

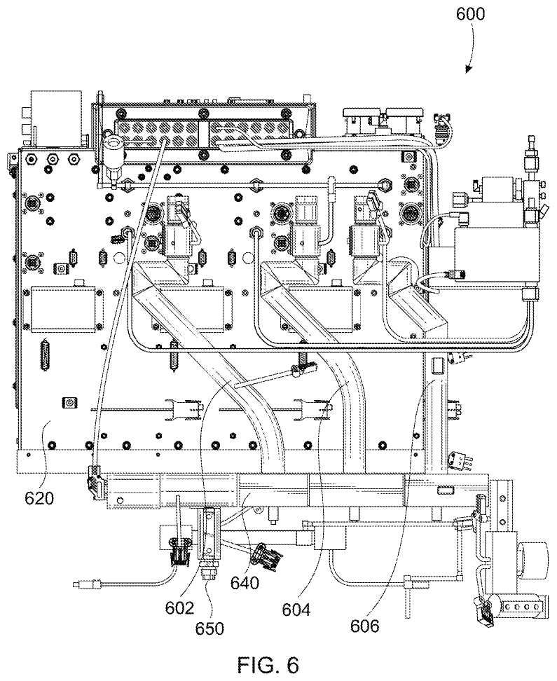

The ampoule 312 may be configured to store a precursor, and may include a first inlet 336 (i.e., first inlet port) for receiving a precursor, a second inlet 334 (i.e., second inlet port) for receiving a carrier gas, and an outlet 332 (i.e., outlet port) for supplying a mixture of the precursor and the carrier gas, or the carrier gas only or the precursor only. In some embodiments, the precursor may be a silicon-containing precursor to form a silicon-containing layer including doped or undoped silicon carbide, e.g., oxygen doped silicon carbide (SiCO), nitrogen doped silicon carbide (SiCN), and nitrogen and oxygen doped silicon carbide (SiOCN). The silicon-containing layer may additionally or alternatively include silicon oxide (SiOx), silicon nitride (SixNy), or oxygen doped silicon nitride (SiON). In some embodiments, the silicon-containing layer may be deposited by ALD or PEALD. The first valve assembly 340 may include multiple valves and gas lines in controlling the flow of the precursor or the carrier gas that flows into and out of the ampoule 312. In some embodiments, the first valve assembly 340 includes a second valve 344 (i.e., carrier gas in valve), configured to open and/or close to control the carrier gas flow from the source gas supply to the ampoule 312, fluidly connecting the second inlet 334 (i.e., second inlet port) to the ampoule 312 and an outlet of a fifth valve 352 in a second valve assembly 350. A lockout safety on-off valve 374 may be optionally positioned downstream from the second valve 344 at the second inlet 334 (i.e., second inlet port) to the ampoule 312 as a safety measure. A third valve 342 (i.e., vapor out valve) may be configured to open and/or close to supply a mixture of the precursor and the carrier gas formed in the ampoule 312 to the process chamber. The third valve 342 (i.e., vapor out valve) may fluidly connect the outlet 332 (i.e., outlet port) of the ampoule 312 with an inner vapor out line 386 in the interior of the precursor delivery system. The inner vapor out line 386 may refer to a vapor out line that is positioned within the housing. While not shown in FIG. 3, the inner vapor out line 386 may be fluidly coupled to a vapor out line (e.g., vapor out line 602, 604, or 606 as illustrated in FIG. 6) exterior to the housing, which ultimately extends to a showerhead fluidly coupled to the process chamber or ultimately extends to a distribution point that fluidly connects to a showerhead. The inner vapor out line 386 may be fluidly coupled to the vapor out line via a valve. In some embodiments, the valve may be coupled to the rear wall of the housing. A lockout safety on-off valve 372 may be optionally positioned upstream from the third valve 342 at the outlet 332 (i.e., outlet port) from the ampoule 312 as a safety measure. A fourth valve 348 is a bypass valve which permits a carrier gas to bypass, or divert around, the ampoule 312, including when at least one of the valves 344 and/or 342 is closed. The fourth valve 348 (i.e., bypass valve) fluidly couples a first junction 378 between the third valve 342 and the fourth valve 348 and a second junction 380 between the second valve 344 and the fourth valve 348. After the first junction 378, e.g., downstream, the carrier gas may flow along the inner vapor out line 386 toward an inlet to the process chamber. The inner vapor out line 386 may refer to a gas line that fluidly connects the third valve 342 or the fourth valve 348 with a vapor out line (not shown) that is fluidly coupled to the inner vapor out line 386, and is located exterior to the precursor delivery system. The inner vapor out line 386 may refer to a gas line section that is positioned in the interior of the precursor delivery system. The inner vapor out line 386 bypasses the second valve assembly 350.

In some embodiments, the second valve assembly 350 may include four valves, such as fifth valve 352, sixth valve 354, seventh valve 356, and eighth valve 358. An on-off valve 362 may be connected downstream from the source gas supply and fluidly connected to a flow controller 360 (e.g., mass flow controller (MFC)). The flow controller 360 may be fluidly connected upstream to an inlet of the fifth valve 352 in the second valve assembly 350. The flow controller 360 may control the supply of a carrier gas such as an inert gas including nitrogen or argon from the source gas supply to the fifth valve 352. In some embodiments, the flow controller 360 is upstream from the fifth valve 352 in the second valve assembly 350, after which there is the second junction 380 in the first valve assembly 340 between the fourth valve 348 and the second valve 344 that is fluidly connected to the second inlet 334 (i.e., second inlet port) of the ampoule 312.

The fifth valve 352 may control the flow of a carrier gas flowing from the flow controller 360 to the second valve 344 (i.e., carrier gas in valve) that is fluidly connected to the optional lockout safety on-off valve 374, and opens and closes the second inlet 334 (i.e., second inlet port) to the ampoule 312. The sixth valve 354 and the seventh valve 356 in the second valve assembly 350 may be fluidly connected to a first valve 346 (i.e. precursor in valve), where the first valve 346 is fluidly connected to the ampoule 312 and a vacuum source (not shown) for maintenance. For example, the sixth valve 354 and seventh valve 356 may be configured to open to remove any remaining precursor from the ampoule 312 and a gas line between the ampoule 312 and the vacuum source in case any maintenance or cleaning of the ampoule 312 is necessary.

The eighth valve 358 in the second valve assembly 350 may be configured to open and/or close to supply a precursor from the precursor source supply to the ampoule 312, and fluidly couple the precursor source supply and the first valve 346 (i.e., precursor in valve) that is fluidly coupled to a first inlet 336 (i.e., first inlet port) of the ampoule 312. A lockout safety on-off valve 376 may be optionally positioned downstream from the first valve 346 as a safety measure. The valves 358, 346, and 376 may control the amount of the precursor stored in the ampoule 312 such that a certain level of the precursor is maintained in the ampoule 312. When valves 358, 346, and 376 are open, the precursor may flow from the precursor source supply to third junction 382, where the precursor may be diverted to a gas line section 384 and flow into the ampoule 312. When at least one of the valves 358, 346, and 376 are closed, the flow of the precursor into the ampoule 312 may be limited. In some embodiments, the gas line section 384 containing the precursor may be a configuration such as a dipstick and may fill the ampoule 312 from the top of the ampoule 312. In other embodiments, the flow path may be a flow path connected to the bottom of the ampoule 312.

The operation of the precursor delivery system may be described with respect to one detachable precursor dispensing assembly in the precursor delivery system as shown in FIG. 3. In some embodiments, each detachable precursor dispensing assembly in the precursor delivery system may operate independently from other detachable precursor dispensing assemblies. Alternately, the operation of more than one detachable precursor dispensing assemblies may be controlled by a controller in accordance with certain process instructions. In operation of the detachable precursor dispensing assembly 310, a carrier gas (e.g., inert gas) from the source gas supply may pass gas lines through the on-off valve 362, the flow controller 360, the fifth valve 352 in the second valve assembly 350, the second valve 344 in the first valve assembly 340, and optionally the safety on-off valve 374 before entering the ampoule 312. In some embodiments, a precursor, which is supplied from the precursor supply source through valves 358 and 346, and optionally valve 376 in the interior of the ampoule 312 may be mixed with the carrier gas within the ampoule 312 to form a mixture. The mixture including the precursor and the carrier gas with a certain mixing ratio may exit the outlet 332 (i.e., outlet port) of the ampoule 312 and pass through the optional safety on-off valve 372 and the third valve 342. The mixture may be delivered through the gas line 386 (i.e., inner vapor out line), which is fluidly coupled to the vapor out line that is exterior to the precursor delivery system (i.e., housing) to a distribution point (shown in FIG. 6), where the mixture may be distributed to one or more process chambers for deposition. For example, the mixture may flow from the distribution point to the showerhead in one or more process chambers. When valves 344 and/or 342 are closed, the carrier gas flowing from the source gas supply may flow through the fourth valve 348 without passing through the ampoule 312. The carrier gas may flow through the gas line 386 into the interior of the process chamber. In some embodiments, the carrier gas flowing through the fourth valve 348 may flow to a foreline proximate to the process chamber, without flowing into the process chamber.

Ordinarily, a detachable precursor gas assembly of the precursor delivery system is designed with many valves and gas lines, such as five or more or eight or more valves in a second valve assembly and an inner vapor out line that passes through the second valve assembly. In some embodiments, the detachable precursor dispensing assembly 310 of the precursor delivery system 300 of the present disclosure is designed with fewer valves and shorter gas lines. For example, the second valve assembly 350 may be designed to have four or fewer valves. The inner vapor out line 386 may bypass the second valve assembly 350, thereby reducing the inner vapor out line gas length.

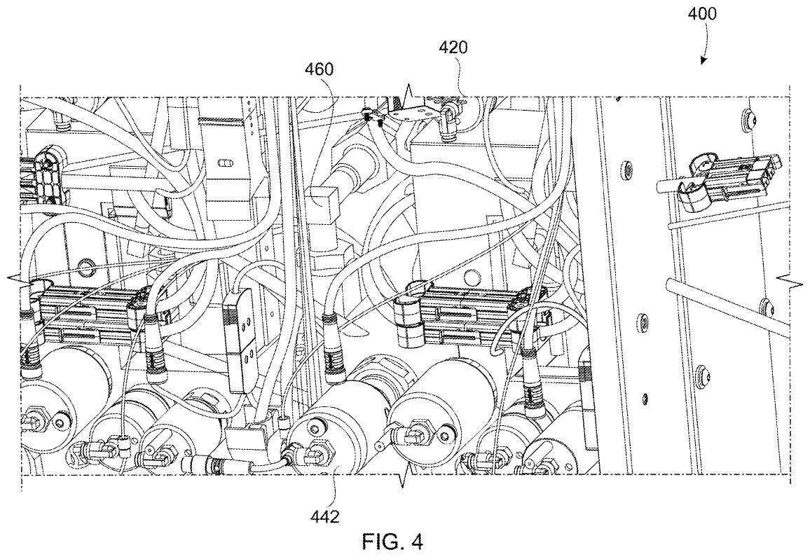

FIG. 4 shows a magnified view of an interior of an example precursor delivery system for the delivery of a precursor and carrier gas according to some embodiments. It is noted that not all components and gas lines for a precursor delivery system are included in FIG. 4. In some embodiments, in each detachable precursor dispensing assembly, a mixture of a precursor and a carrier gas may be formed in the ampoule (not shown here), flow from an outlet (i.e., outlet port) of the ampoule to pass through a third valve 442 (i.e., vapor out valve). The third valve 442 of FIG. 4 may correspond to the third valve of FIG. 3. Subsequently, the mixture of the precursor and the carrier gas may pass from the third valve 442, an inner vapor out line (not shown in FIG. 4; corresponding to inner vapor our line 386 in FIG. 3) that is fluidly coupled to an elbow valve 460, which may also be coupled to the rear cover 420 of a precursor delivery system 400. The elbow valve 460 may be fluidly coupled to the vapor out line that is exterior to the delivery system. In some embodiments, the elbow valve 460 may be positioned within the precursor delivery system. In some embodiments, the gas line length from the third valve 442 through the elbow valve 460 to the rear cover 420 may be about 16 to about 25 cm, or about 19 to about 22 cm.

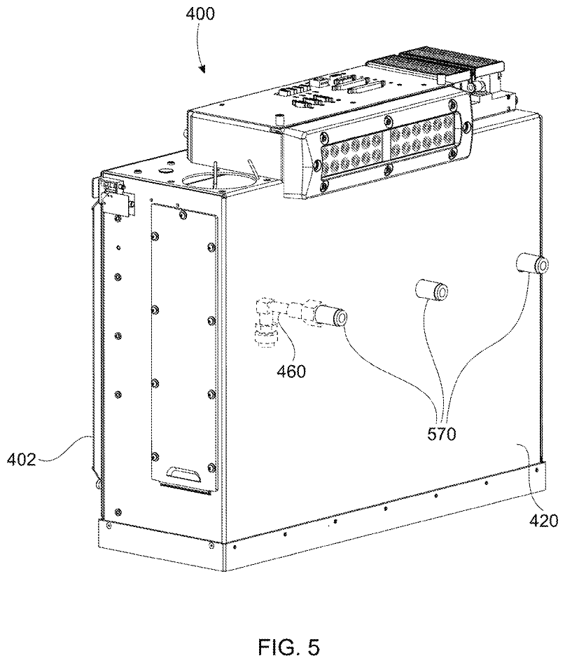

FIG. 5 shows an exterior of the example precursor delivery system of FIG. 4 for delivery of a precursor and carrier gas according to some embodiments. It is noted that FIG. 5 is not limited to the precursor delivery system having three detachable precursor dispensing assemblies. Instead, FIG. 5 may also be applied to the precursor delivery system having any number of detachable precursor dispensing assemblies operating independently or in combination with other detachable precursor dispensing assemblies in a precursor delivery system. FIG. 5 illustrates that the elbow valve 460 is fluidly connected to an outlet 570, where the outlet 570 extends from the rear cover 420. It is to be understood that while only one elbow valve 460 is shown in FIG. 5, at least two additional elbow valves may also fluidly couple the ampoule in each detachable precursor dispensing assembly to the outlet 570 that extends from the rear cover 420. In some embodiments, the location of the elbow valve 460, combined with an inner vapor out line that bypasses the second valve assembly, is designed to provide a reduced flow distance for a mixture of a precursor and a carrier gas, or a reduced flow distance for the carrier gas only, from the ampoule to the process chamber. The reduced flow distance from the ampoule to the process chamber can shorten purge times and improve process gas timing in deposition processes. The reduced flow distance may reduce the overall time for completing a deposition process and increase throughput.

FIG. 6 shows an example rear view of an example precursor delivery system 600 according to some embodiments. It is noted that FIG. 6 is not limited to the precursor delivery system having three detachable precursor dispensing assemblies. Instead, FIG. 6 may also be applied to the precursor delivery system having any number of detachable precursor dispensing assemblies operating independently or in combination with other detachable precursor dispensing assemblies in a precursor delivery system. In some embodiments, the precursor delivery system 600 may include first, second, and third vapor out lines 602, 604, and 606 for fluidly coupling the three vapor out lines 602, 604, and 606 with three corresponding detachable precursor dispensing assemblies populated in the example precursor delivery system, respectively. In some embodiments, each vapor line (e.g., first, second, or third vapor out lines 602, 604, or 606 illustrated in FIG. 6) may be fluidly coupled to the inner vapor out line 386 in each corresponding detachable precursor dispensing assembly. The mixture of precursor and carrier gas, or carrier gas only, may flow from an ampoule 312 in each detachable precursor dispensing assembly through the inner vapor out line in the interior of the precursor delivery system, and flow through the vapor out line (i.e., one of the first, second, or third vapor out lines 602, 604, and 606) as illustrated in FIG. 6.

In some embodiments, each of the first, second, and third vapor out lines 602, 604, and 606 may be fluidly and detachably coupled to corresponding outlets 570 (as shown in FIG. 5) formed on the rear cover 620 of the precursor delivery system 600. The mixture of precursor and carrier gas, or carrier gas only, may be flow from one or more outlets 570 to a conduit 640 that is fluidly coupled to the first, second, and third vapor out lines 602, 604, and 606. The conduit 640 may receive the mixture or the carrier gas from the first, second, and third vapor out lines 602, 604, and 606. In some embodiments, the conduit 640 may extend in a horizontal direction, and may be positioned proximate to the bottom of the precursor delivery system 600 or below the precursor delivery system 600. At each of the intersections of the first, second, and third vapor out lines 602, 604, and 606, a valve may regulate delivery of the mixture of the precursor and carrier gas, or carrier gas only, to the conduit 640. That way, the precursor delivery system 600 is configured to deliver a first chemistry (e.g., first precursor and carrier gas), a second chemistry (e.g., second precursor and carrier gas), or a third chemistry (e.g., third precursor and carrier gas) to the conduit 640.

In some embodiments, additional gas such as inert gas, purge gas, or carrier gas (e.g., nitrogen) may be provided to the conduit 640. Rather than being limited to a particular channel, the additional gas may carry through any of the first, second, and third vapor out lines 602, 604, and 606. In some cases, the additional gas may be provided with the mixture of the precursor and carrier gas exiting the one of the first, second, and third vapor out lines 602, 604, and 606. The additional gas may serve as a push gas for the mixture or carrier gas for improved gas flow. In some embodiments, a valve may regulate delivery of the additional gas to the conduit 640.

In some embodiments, a manometer may be located outside the precursor delivery system 600 and coupled to the conduit 640 to monitor a pressure of a mixture or a carrier gas flowing in the conduit 640. Placement of the manometer outside of the precursor delivery system 600 (i.e., on an exterior of the precursor delivery system 600 rather than an interior) improves accessibility and serviceability of the precursor delivery system 600 while simplifying the design of the precursor delivery system 600.

The conduit 640 may include a distribution point 650 (i.e., opening) that may be fluidly coupled to one or more showerheads in one or more respective process chambers. In some embodiments, a mixture of a precursor and a carrier gas, or a carrier gas only, may pass through the distribution point 650. This supplies the precursor and carrier gas, or carrier gas only, to one or more process chambers via one or more respective showerheads as part of a deposition process. By having first, second, and third vapor out lines 602, 604, and 606 corresponding to a first, second, and third detachable precursor dispensing assemblies, the precursor delivery system 600 is configured to deliver at least three different chemistries to the one or more process chambers as part of the deposition process.

In one example, the length of each of the first, second, and third vapor out lines 602, 604, and 606 may be about 37 cm to about 51 cm. In some embodiments, the combined length of an inner vapor out line 386 and one of the first, second, and third vapor out lines 602, 604, and 606 may be about 63 to about 76 cm.

In some embodiments, a mixture flowing out of the ampoule may flow to the distribution point 650 without passing through any additional valves, e.g., on-off valves. For example, referring back to the flow diagram in FIG. 3, a mixture flowing out of the outlet (i.e., outlet port) 332 of the ampoule 312 may directly flow through the inner vapor out line 386, without passing through any valve in the second valve assembly 350. This flow path allows the mixture to not flow through an additional valve. As such, this may reduce the distance a mixture including a precursor flows from the ampoule 312 to the distribution point 650 (as shown in FIG. 6), thereby reducing the time to introduce the precursor in the mixture into the process chamber. The flow path as shown in FIGS. 3 and 6 may also reduce the time a carrier gas flows from the source gas supply into a process chamber, thereby reducing a purge time prior to and/or after the deposition process. As a result, the overall time for the entire deposition process may be curtailed, and the throughput would be increased. The precursor delivery system according to some embodiments also reduce the number of extra valves since the precursor would not pass through any valve while flowing from the third valve 342 to the distribution point 650 (as shown in FIG. 6). Further, the reduced length of the gas line may reduce the material cost and maintenance cost.

Additionally, each of the precursor dispensing assemblies 210, 220, and 230 is detachable from the precursor delivery system 200. This enables one or two of the detachable precursor dispensing assemblies 210, 220, and 230 to be easily removed from the precursor delivery system 200. As a result, the precursor delivery system 200 of the present disclosure can be modularized to deliver one chemistry, two chemistries, or three chemistries.

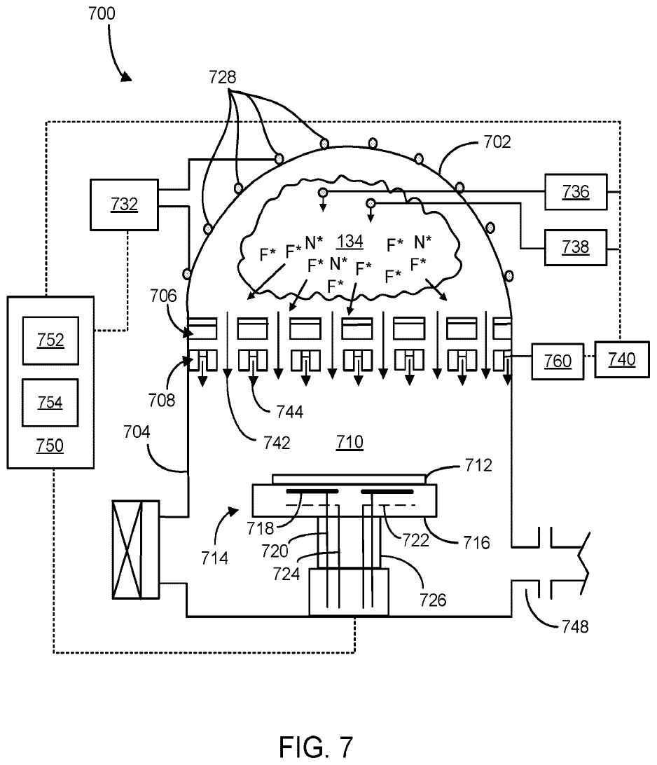

FIG. 7 shows a schematic illustration of an example plasma processing apparatus according to some embodiments. It will be understood that the plasma processing apparatus in FIG. 7 may be used to deposit a film by ALD, PEALD, CVD, or PECVD, and/or to treat the process chamber by delivering a plasma flow according to some embodiments. In some embodiments, the apparatus in FIG. 7 may be used to deposit a film by CVD or ALD. In some embodiments, the apparatus in FIG. 7 may be used to deposit a film by remote plasma CVD or remote plasma ALD.

The plasma processing apparatus 700 in FIG. 7 includes a remote plasma source 702 separated from a process chamber 704. The remote plasma source 702 is fluidly coupled with the process chamber 704 via a gas distributor or a showerhead 706. A coil 728 may be arranged around the remote plasma source 702, where the remote plasma source 702 includes an outer wall (e.g., quartz dome). The outer wall may be a semicircle shape or an oval shape. In some embodiments, the outer wall may be made of ceramic material. The coil 728 is electrically coupled to a plasma generator controller 732, which may be used to form and sustain plasma within a plasma region 734 via an inductively coupled plasma generation, a capacitively coupled plasma generation, a microwave plasma generation, a DC plasma generation, or a laser-created plasma generation. In some embodiments, the plasma generator controller 732 may include a power supply for supplying power to the coil 728, where the power can be in a range between about 500 watts (W) and about 15 kilowatts (kW) per station, or between about 2 kW and about 10 kW per station during plasma generation. In some embodiments, electrodes or antenna for parallel plate plasma generation, an inductively coupled plasma generation, a capacitively coupled plasma generation, a microwave plasma generation, a DC plasma generation, or a laser-created plasma generation may be used to generate a continuous supply of radicals via plasma excitation. In some embodiments, radicals and/or ions may be generated by inductively coupled plasma generation. In some embodiments, radicals and/or ions may be generated by a microwave plasma, a direct current (DC) plasma, or a laser-created plasma. Regardless of the mechanism used to ignite and sustain the plasma in the plasma region 734, radical species may continuously be generated using plasma excitation.

A supply of ions and radicals may be continuously generated within the plasma region 734 while one or more source gases are being supplied to the remote plasma source 702. Ions generated in the plasma region 734 may be filtered out by the ion filter of the showerhead 706. That way, radicals generated in the plasma region 734 may be supplied to a substrate 772 in the process chamber 704 while limiting ion bombardment. Conditions in the remote plasma source 702, including a composition of the source gas provided to the remote plasma source 702 and RF power supplied to the coil 728, may be controlled to optimize generation of desired radical species in the plasma region 734.

In FIG. 7, a source gas supply 736 is fluidly coupled with the remote plasma source 702 for supplying the source gas. In some embodiments, one or more source gases may include an oxygen-containing reactant such as oxygen (O₂), carbon dioxide (CO₂), or nitrogen dioxide (NO₂), fluorine-containing reactant such as nitrogen trifluoride (NF₃), fluorine (F₂), carbon tetrafluoride (CF₄), or carbon hexafluoride (C₂F₆), hydrogen-containing reactant such as hydrogen (H₂) or methane (CH₄), inert gas such as argon (Ar), or nitrogen-containing reactant such as nitrogen (N₂), ammonia (NH₃), diazene (N₂H₂), or hydrazine (N₂H₄), carbon-containing reactant such as acetylene (C₂H₂), or propene (C₃H₆), or mixtures thereof.

The films to be deposited may be a silicon based film including doped or undoped silicon carbide, e.g., oxygen doped silicon carbide (SiCO), nitrogen doped silicon carbide (SiCN), and nitrogen and oxygen doped silicon carbide (SiOCN). For many, doped silicon carbides have at most about 50% atomic of dopant atoms, whether those atoms are oxygen, nitrogen, or atoms of another element. The doping level provides desired film properties. The silicon-containing film may also include silicon oxide (SiOx), silicon nitride (SixNy), or oxygen doped silicon nitride (SiON). A gas mixture supplied to the remote plasma source for film deposition process may include, but not limited to oxygen (O₂), carbon dioxide (CO₂), nitrogen dioxide (NO₂), hydrogen (H₂), methane (CH₄), argon (Ar), nitrogen (N₂), ammonia (NH₃), diazene (N₂H₂), hydrazine (N₂H₄), acetylene (C₂H₂), propene (C₃H₆), or mixtures thereof.

Types of radical species generated in the remote plasma source 702 may be determined by the source gases supplied to the remote plasma source 702. In some embodiments, depending on the nature of the source gases, a mixture of radical species may include hydrogen radicals (H*), nitrogen radicals (N*), oxygen radicals (O*), fluorine radicals (F*), amine radicals (NH*, NH₂*), carbon radicals (C*), or a combination thereof. These radicals may be generated in the plasma region 734 under approximately steady-state conditions during steady-state film deposition or chamber treatment as controlled by the plasma generator controller 732, though transients may occur at the beginning and end of film deposition and/or chamber treatment.

An additional gas supply 738 is fluidly coupled with the remote plasma source 702 for supplying the one or more additional gases. While the embodiment in FIG. 7 depicts the gas mixture of the source gas and the one or more additional gases being introduced through separate gas outlets, it will be understood that the gas mixture may be introduced directly into the remote plasma source 702. That is, a pre-mixed dilute gas mixture may be supplied to the remote plasma source 702 through a single gas outlet. The one or more additional gases can include a carrier gas. Non-limiting examples of additional gases may include helium (He), neon (Ne), argon (Ar), krypton (Kr), xenon (Xe), and nitrogen (N₂). The one or more additional gases may support or stabilize steady-state plasma conditions within the remote plasma source 702 or aid in transient plasma ignition or extinction processes.

In some embodiments, a gas conduit from the gas source (not shown) through the source gas supply 736 into the remote plasma source 702, and/or a gas conduit from a gas source (not shown) through the additional gas supply 738 into the remote plasma source 702 may be designed to withstand high gas flow rate according to some embodiments.

In some embodiments, one or more co-reactants, which are not the primary silicon-containing precursor or a hydrogen radical, are introduced during the deposition reaction. In some embodiments, the plasma processing apparatus is configured to introduce the co-reactant through the source gas supply 736 or the additional gas supply 738, in which case the co-reactant is at least partially converted to plasma. Examples of such co-reactants include carbon dioxide (CO₂), carbon monoxide (CO), water (H₂O), methanol (CH₃OH), oxygen (O₂), ozone (O₃), nitrogen (N₂), nitrous oxide (N₂O), ammonia (NH₃), diazene (N₂H₂), methane (CH₄), ethane (C₂H₆), acetylene (C₂H₂), ethylene (C₂H₄), diborane (B₂H₆), and a combination thereof. Other examples of such co-reactants may include silicon-containing precursors of a different chemistry than the primary silicon-containing precursor.

Plasma-activated species 742, such as excited nitrogen, hydrogen, carbon, oxygen, fluorine, and/or amine radicals, flow out of the remote plasma source 702 and into the process chamber 704 via the showerhead 706. In some embodiments, plasma-activated species 742 may be the plasma flow. Plasma-activated species 742 within the showerhead 706 and within the process chamber 704 are generally not subject to continued plasma excitation therein. The showerhead 706 may have a plurality of gas ports to diffuse the flow of plasma-activated species 742 into the process chamber 704. In some embodiments, the plurality of gas ports may be mutually spaced apart. In some embodiments, the plurality of gas ports may be arranged as an array of regularly spaced apart channels or through-holes extending through a plate separating the remote plasma source 702 and the process chamber 704. The plurality of gas ports may smoothly disperse and diffuse exiting radicals (including plasma-activated species 742) from the remote plasma source 702 into the deposition zone 710 of the process chamber 704 while filtering out ions. Once passing through the plurality of gas ports in the showerhead 706, plasma-activated species 742 (i.e., plasma flow) may flow further in a downward direction. In some embodiments, a plasma flow may include fluorine species and other plasma-activated species.

With the delivery of the plasma-activated species 742 to the process chamber 704 from the showerhead 706, one or more silicon-containing precursors 744 (or other process gases) may be introduced into the process chamber 704 for depositing a silicon based film. The silicon-containing precursors 744 may be introduced via gas outlets 708, where the gas outlets 708 may be fluidly coupled with one or more silicon-containing precursor supply sources 740. One or more precursor source supplies, such as one or more silicon-containing precursor sources 740 may be fluidly coupled to a precursor delivery system 760 according to some embodiments. The precursor delivery system 760 may be further provided with a heating element to maintain the temperature of a silicon-containing precursor at a certain temperature. As discussed above, the precursor delivery system 760 may be configured to supply at least three different chemistries or precursors to the process chamber 704 via gas outlets 708. The gas outlets 708 may include mutually spaced apart openings so that the flow of the silicon-containing precursors 744 may be introduced in a direction parallel with the plasma-activated species 742 flowing from the showerhead 706. In some embodiments, the gas outlets 708 may be located downstream from the showerhead 706. In some embodiments, the gas outlets 708 are part of the showerhead 706 such as in a dual-plenum showerhead. The dual-plenum showerhead may provide separate outlets/passages for the plasma-activated species 742 and the silicon-containing precursors 744 to avoid mixing in the showerhead 706. That way, the silicon-containing precursors 744 may flow into the process chamber 704 via the showerhead 706 without exposure to plasma in the remote plasma source 702. The gas outlets 708 may be located upstream from the deposition zone 710 and the substrate 712. The deposition zone 710 is located within the interior of the process chamber 704 between the gas outlets 708 and the substrate 712.

In some embodiments, a silicon-containing precursor may include at least one or more Si-Si bonds and/or at least one or more Si—H bonds. Silicon-containing precursors suitable for use in accordance with disclosed embodiments may include: silane (SiH₄), disilane (Si₂H₆), and organosilanes such as methylsilane, ethylsilane, isopropylsilane, t-butylsilane, dimethylsilane, diethylsilane, di-t-butylsilane, allylsilane, sec-butylsilane, thexylsilane, isoamylsilane, t-butyldisilane, di-t-butyldisilane, and the like.

In some embodiments, silicon-containing precursor may also include a halosilane. A halosilane includes at least one halogen group and may or may not include hydrogens and/or carbon groups. Examples of halosilanes are iodosilanes, bromosilanes, chlorosilanes, and fluorosilanes. Specific chlorosilanes are tetrachlorosilane, trichlorosilane, dichlorosilane, monochlorosilane, chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, and the like.

In some embodiments, silicon-containing precursor may also include an aminosilane. An aminosilane includes at least one nitrogen atom bonded to a silicon atom, but may also contain hydrogens, oxygens, halogens, and carbons. Examples of aminosilanes are mono-, di-, tri- and tetra-aminosilane (H₃Si(NH₂), H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bis(tert-butylamino)silane (SiH₂(NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃ and the like. A further example of an aminosilane is trisilylamine (N(SiH₃)). In some embodiments, an aminosilane that has two or more amine groups attached to the central Si atom may be used. These may result in less damage than aminosilanes having only a single amine group attached.

Further examples of silicon-containing precursors include trimethylsilane (3MS); ethylsilane; butasilanes; pentasilanes; octasilanes; heptasilane; hexasilane; cyclobutasilane; cycloheptasilane; cyclohexasilane; cyclooctasilane; cyclopentasilane; 1,4-dioxa-2,3,5,6-tetrasilacyclohexane; diethoxymethylsilane (DEMS); diethoxysilane (DES); dimethoxymethylsilane; dimethoxysilane (DMOS); methyl-diethoxysilane (MDES); methyl-dimethoxysilane (MDMS); octamethoxydodecasiloxane (OMODDS); tert-butoxydisilane; tetramethylcyclotetrasiloxane (TMCTS); tetraoxymethylcyclotetrasiloxane (TOMCTS); triethoxysilane (TES); triethoxysiloxane (TRIES); and trimethoxysilane (TMS or TriMOS).

In addition to silicon-containing precursors, the environment adjacent the substrate may include one or more radical species, preferably in a substantially low energy state. Radicals may include hydrogen radicals, nitrogen radicals, oxygen radicals, amine radicals, carbon radicals, or a combination thereof. In some embodiments, all, or substantially all, or a substantial fraction of the hydrogen atom radicals can be in the ground state, e.g., at least about 90% or 95% of the hydrogen atom radicals adjacent the substrate may be in the ground state. In some implementations, when the excited hydrogen atom radicals lose their energy, or relax, the excited hydrogen atom radical may become a substantially low energy state hydrogen atom radical or a ground state hydrogen atom radical. Hydrogen atom radicals in a substantially low energy state or ground state can be capable of selectively breaking Si—H and Si—Si bonds while generally preserving Si—O, Si—N, and/or Si—C bonds. In some implementations, process conditions may be provided so that excited hydrogen atom radicals lose energy or relax to form substantially low energy state or ground state hydrogen atom radicals.

In a film deposition process, a substantial fraction of the silicon-containing precursors 744 may be prevented from mixing with plasma-activated species 742 in the showerhead 706 or adjacent to the showerhead 706. In some embodiments, silicon-containing precursors 744 may be delivered to the substrate 712 in dose phases of ALD cycles separate from plasma-activated species 742 delivered to the substrate 712 during plasma exposure phases of the ALD cycles. Adsorbed silicon-containing precursors 744 may react with radicals of the plasma-activated species 742 during plasma exposure phases of the ALD cycles to deposit film. In some embodiments, silicon-containing precursors 744 may be delivered to the substrate 712 in a continuous manner to interact with plasma-activated species 742 in a deposition zone 710 to deposit a film by CVD. The radicals of the plasma-activated species 742 may mix with the silicon-containing precursors 744 in the gas phase during CVD formation of the film.

Gases may be removed from the process chamber 704 via an outlet 748 that is fluidly coupled to a pump (not shown). Thus, radical species or purge gases may be removed from the process chamber 704.

The substrate 712 is supported on a substrate support structure or wafer pedestal 714 (i.e., pedestal). The pedestal 714 may be configured with lift pins or other movable support members to position the substrate 712 within a deposition zone 710. The substrate 712 may be moved to a position closer or farther from the showerhead 706. The pedestal 714 may also adjust the temperature of the substrate 712 in some embodiments, which can provide some selective control over thermally activated surface reactions on the substrate 712.

The pedestal 714 may be prepared by ceramic materials. In one embodiment, the pedestal 714 may be made of aluminum nitride, which may be suitable in a high temperature process, e.g., a plasma processing environment without causing any thermal damage to the pedestal 714. Other surfaces of the process chamber 704 may be formed of ceramic materials such as aluminum nitride.

In some embodiments, the pedestal 714 includes an electrostatic chuck 716. The electrostatic chuck 716 may include one or more electrostatic clamping electrodes 718 embedded within a body of the electrostatic chuck 716. In some embodiments, the one or more electrostatic clamping electrodes 718 may be coplanar or substantially coplanar. The electrostatic clamping electrodes 718 may be powered by a DC power source or DC chucking voltage (e.g., between about 200 V to about 2000 V) so that the substrate 712 may be retained on the electrostatic chuck 716 by electrostatic attractive forces. Power to the electrostatic clamping electrodes 718 may be provided via first electrical lines 720. The electrostatic chuck 716 may further include one or more heating elements 722 embedded within the body of the electrostatic chuck 716. The one or more heating elements 722 may include resistive heaters. In some embodiments, the one or more heating elements 722 are positioned below the one or more electrostatic clamping electrodes 718. The one or more heating elements 722 may be configured to heat the substrate 712 to a temperature greater than about 450 °C, greater than about 500 °C, greater than about 550 °C, greater than about 600 °C, or greater than about 650 °C. The one or more heating elements 722 provide selective temperature control to the substrate 712. Power to the one or more heating elements 722 may be provided via second electrical lines 724.

In some embodiments, a thermal shield (not shown) may be positioned underneath the pedestal 714. The thermal shield serves as a thermal insulator under the pedestal 714 to mitigate heat loss via thermal radiation, thereby reducing the amount of power needed to maintain the pedestal 714 at a particular elevated temperature and also preventing other components within the process chamber 704 from overheating due to excess heat radiated from the pedestal 714. For example, the thermal shield may be radially offset from the stem 726 and may have a thin annular-shaped body with a high view factor relative to the underside of the electrostatic chuck 716. Thus, the annular-shaped thermal shield may reduce radiative heat loss from the pedestal 714.

The controller 750 may contain instructions for controlling process conditions for the operation of the plasma processing apparatus 700. The controller 750 will typically include one or more memory devices and one or more processors. The processor may include a CPU or computer, analog and/or digital input/output connections, stepper motor controller boards, etc. Instructions for implementing appropriate control operations are executed on the processor. These instructions may be stored on the memory devices associated with the controller 750 or they may be provided over a network.

In certain embodiments, the controller 750 controls all or most activities of the plasma processing apparatus 700 described herein. For example, the controller 750 may control all or most activities of the plasma processing apparatus 700 associated with film deposition and/or a chamber treatment. In some embodiments, the controller 750 includes a processor system 752 (e.g., microprocessor) configured to execute instructions held in a data system 754 (e.g., memory). In some embodiments, the controller 750 may be in communication with the plasma generator controller 732 to control plasma parameters and/or conditions in the remote plasma source 702. In some embodiments, the controller 750 may be in communication with the pedestal 714 to control pedestal elevation (substrate position), electrostatic chucking and dechucking, and temperature. In some embodiments, the controller 750 may control other processing conditions, such as RF power settings, frequency settings, duty cycles, pulse times, pressure within the process chamber 704, pressure within the remote plasma source 702, gas composition, and gas flow rates from the source gas supply 736, gas composition, and gas flow rates from the additional gas supply 738 and other sources, temperature of the pedestal 714, and temperature of the process chamber 704, among other processing conditions.

In some embodiments, the controller 750 may include instructions configured to perform operations such as heating the process chamber 704 to a predetermined temperature, delivering a plasma flow from the remote plasma source 702 into the process chamber 704 through the showerhead 706, and displacing a gaseous contaminant with the plasma flow from the showerhead 706. In some embodiments, the plasma flow includes a fluorine-containing reactant such as nitrogen trifluoride. For example, the plasma flow includes gas species comprising oxygen, fluorine, nitrogen, argon, or a combination thereof. In some embodiments, the predetermined temperature may range from 450 °C to 650 °C.

In some embodiments, the controller 750 may include instructions configured to perform operations such as introducing a dose of a silicon-containing precursor 744 in a vapor phase to adsorb on the substrate 712, and exposing the substrate 712 to plasma-activated species 742 of a source gas generated in the remote plasma source 702, where the adsorbed silicon-containing precursor 744 reacts with the plasma-activated species 742 to deposit a silicon-containing film. In some embodiments, the controller 750 may introduce a purge gas between the dose of the silicon-containing precursor 744 and exposure to the plasma-activated species 742 in an ALD process. In some embodiments, the silicon-containing precursor 744 may be introduced from a precursor delivery system 760 having at least three different channels or detachable precursor dispensing assemblies. The precursor delivery system 760 may be designed with gas lines close to the showerhead 706 and close to an exhaust as discussed above.

In some embodiments, the plasma processing apparatus 700 may include a user interface associated with controller 750. The user interface may include a display screen, graphical software displays of the plasma processing apparatus 700 and/or process conditions, and user input devices such as pointing devices, keyboards, touch screens, microphones, etc.

The computer program code for controlling the above operations can be written in any conventional computer readable programming language: for example, assembly language, C, C++, Pascal, Fortran, or others. Compiled object code or script is executed by the processor to perform the tasks identified in the program.

Signals for monitoring the process may be provided by analog and/or digital input connections of the controller 750. The signals for controlling the process are output on the analog and digital output connections of the processing system.

Broadly speaking, the controller 750 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller 750 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials (e.g., silicon nitride), surfaces, circuits, and/or dies of a wafer.

The controller 750, in some embodiments, may be a part of or coupled to a computer that is integrated with, coupled to the system, otherwise networked to the system, or a combination thereof. For example, the controller 750 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller 750 receives instructions in the form of data, which specify parameters for each of the processing steps to be performed during one or more operations. It should be understood that the parameters may be specific to the type of process to be performed and the type of tool that the controller 750 is configured to interface with or control. Thus, as described above, the controller 750 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Example systems according to some embodiments herein may include an ALD chamber or module, a PEALD chamber or module, a CVD chamber or module, a PECVD chamber or module, and any other semiconductor processing systems that may be associated or used in the fabrication and/or manufacturing of semiconductor wafers.

In some embodiments, a process chamber for an example plasma processing apparatus may be used, depending on a process recipe, to deposit a thin layer by any suitable deposition method such as ALD, PEALD, CVD, or PECVD, and/or to clean the interior surfaces of the process chamber according to embodiments herein.

In some embodiments, the process chamber may include a remote plasma source positioned on the top portion of the process chamber. The remote plasma source may be a dome, and include a coil around the remote plasma source. The remote plasma source may include a plasma region within the remote plasma source. The remote plasma source may be fluidly coupled to the process chamber via a showerhead.

In some embodiments, a precursor delivery system may be provided to a process chamber to supply at least three precursors to a substrate in the process chamber. The precursor delivery system may be configured to detachably receive at least three detachable precursor dispensing assemblies. Each detachable precursor dispensing assembly may include an ampoule that can store a precursor, and supply up to three different precursors to the process chamber. Each precursor may be a liquid precursor or a gas precursor, and may be mixed with a carrier gas before being introduced in the process chamber. Each precursor may be a silicon-containing precursor. In some embodiments, the precursor may take a reduced time in flowing from the ampoule to the process chamber, thereby reducing a purge time prior to and/or after deposition operation, and increasing throughput. The precursor delivery system according to some embodiments includes a reduced number of valves and fittings, thereby reducing the manufacturing cost, and improving the serviceability of the precursor delivery system.

### Conclusion

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A precursor delivery system for supplying a precursor to a process chamber, the precursor delivery system comprising:
a housing comprising a front cover, a rear cover, a top cover, a bottom cover, and two side covers; and
a detachable precursor dispensing assembly detachably coupled to the housing and configured to supply the precursor to the process chamber, wherein the detachable precursor dispensing assembly comprises:
an ampoule configured to receive and supply the precursor to the process chamber; and
a first valve assembly fluidly coupled to the ampoule, the first valve assembly comprising:
a first valve fluidly coupled with a first inlet to the ampoule and a precursor source supply;
a second valve fluidly coupled with a second inlet to the ampoule and a source gas supply;
a third valve fluidly coupled with an outlet of the ampoule and an inner vapor out line; and
a fourth valve fluidly coupled with a first junction between the second valve and the fourth valve, and a second junction between the third valve and the fourth valve; and
a controller for controlling operation of the precursor delivery system.

2. The precursor delivery system of claim 1, wherein the detachable precursor dispensing assembly further comprises a second valve assembly, the second valve assembly comprising:
a fifth valve fluidly coupled with the second valve and a flow controller;
a sixth valve and a seventh valve fluidly coupled with the first valve and a vacuum source; and
an eighth valve fluidly coupled with the precursor source supply with the first valve.

3. The precursor delivery system of claim 2, wherein the inner vapor out line bypasses the second valve assembly.

4. The precursor delivery system of claim 2, wherein the second valve assembly is positioned above the first valve assembly.

5. The precursor delivery system of claim 1, further comprising:
a vapor out line detachably coupled to the rear cover of the housing and fluidly coupled to the ampoule of the detachable precursor dispensing assemblies; and
a conduit fluidly coupled to the vapor out line, wherein the conduit comprises a distribution point that is fluidly coupled to a showerhead of the process chamber,
wherein the conduit is positioned proximate to the bottom of or below the precursor delivery system.

6. The precursor delivery system of claim 1, further comprising a manometer positioned outside the housing, wherein the manometer is fluidly coupled to the conduit.

7. The precursor delivery system of claim 5, further comprising:
an elbow valve that fluidly couples the inner vapor out line with the vapor out line.

8. The precursor delivery system of claim 1, wherein the precursor includes a silicon-containing precursor.

9. An apparatus for processing one or more substrates, the apparatus comprising:
one or more process chambers, each process chamber comprising:
a chuck for supporting a substrate; and
a precursor delivery system for supplying one or more precursors into the process chamber for forming a film, the precursor delivery system comprising:
a housing comprising a front cover, a rear cover, a top cover, a bottom cover, and two side covers; and
one or more detachable precursor dispensing assemblies detachably received in the housing, each of the one or more detachable precursor dispensing assemblies comprising;
an ampoule configured to store the precursor; and
a first valve assembly fluidly coupled to the ampoule, the first valve assembly comprising:
a first valve fluidly coupled with a first inlet to the ampoule and a precursor source supply;
a second valve fluidly coupled with a second inlet to the ampoule and a source gas supply;
a third valve fluidly coupled with an outlet of the ampoule and an inner vapor out line; and
a fourth valve fluidly coupled with a first junction between the second valve and the fourth valve, and a second junction between the third valve and the fourth valve; and
a controller for controlling operation of the precursor delivery system, and
a controller comprising program instructions for:
causing the ampoule to receive the precursor from the precursor source supply;
causing a carrier gas to flow from the source gas supply to the ampoule to form a mixture including the precursor and the carrier gas; and
causing the mixture to flow from the ampoule into the process chamber.

10. The apparatus of claim 9, wherein the apparatus is configured for atomic layer deposition, plasma enhanced atomic layer deposition, chemical vapor deposition, or plasma enhanced chemical vapor deposition.
